(19) United States
(12) Patent Application Publication
(10) Pub. No.: US 2015/0197918 A1
(43) Pub. Date: Jul. 16, 2015

(54) THIN FILM COATING FOR LINKAGE PIN

(71) Applicant: CATERPILLAR INC., Peoria, IL (US)

(72) Inventors: Bao FENG, Dunlap, IL (US); Hyung YOON, Peoria, IL (US); Ronald Mark GINN, Morton, IL (US)

(73) Assignee: CATERPILLAR INC., Peoria, IL (US)

(21) Appl. No.: 14/662,374

(22) Filed: Mar. 19, 2015

Related U.S. Application Data
(63) Continuation-in-part of application No. 14/152,372, filed on Jan. 10, 2014.

(51) Int. Cl. E02F 9/00; C23C 16/27; C23C 14/34

(52) U.S. Cl. CPC E02F 9/006; C23C 14/3414; C23C 16/276

(57) ABSTRACT

A linkage pin joint assembly may include a portion of a first machine member having a first bore, a portion of a second machine member having a second bore, and a linkage pin pivotally interconnecting at least the first and second machine members. The linkage pin may extend between the first and second machine members, and be positioned at least partially within the first bore of the first machine member and the second bore of the second machine member. The linkage pin may extending at least partially through the first and second bores and pivotally support the first and second machine members relative to each other. The linkage pin may be coated with a diamond-like carbon (DLC) coating over at least a portion of an outer diameter surface of the linkage pin, the coating providing a contact layer between the outer diameter surface of the linkage pin and at least one of a mating inner diameter surface of a joint bushing positioned within one of the first and second bores through the first and second machine members and a mating inner diameter surface of one of the first and second bores.

### RELATED APPLICATIONS

This application is a continuation-in-part application of U.S. application Ser. No. 14/152,372, filed Jan. 10, 2014, the contents of which are expressly incorporated herein by reference.

### TECHNICAL FIELD

The present disclosure relates generally to linkage pins and, more particularly, to linkage pins with a thin film coating.

### BACKGROUND

Many earth-working machines, such as, for example, loaders, tractors, and excavators, include linkage pin assemblies at the joints between parts of the machine that move relative to each other during operation of the machine. Such linkage pin assemblies include linkage pins that pivotally or rotatably support various structural members and other components of the machine relative to each other, and that withstand shear, tensile, compressive, and torsional stresses exerted on the structural members and other components during operation of the machine to perform work. Due to wear from abrasion and impacts experienced during use, the maintenance costs for these linkage pins and linkage pin assemblies often constitute a large percentage of the total costs associated with operating the earth-working machines.

A known assembly for coupling links of a track assembly for heavy machinery is disclosed in U.S. Patent Application Publication No. 2012/0267947 by Johannsen et al. (“the '947 publication”). A cartridge assembly disclosed in the '947 publication includes a pin accommodated within an inner bushing, which is, in turn, accommodated within an outer bushing. End portions of the inner bushing are surrounded by inserts, and end portions of the pin are surrounded by collars. The pin is provided with a central, axially oriented lubricant channel, which serves as a reservoir for lubricant and delivers lubricant to a gap between the pin and the inner bushing, and to a gap between the inner bushing and the outer bushing. The lubricant is retained by seals positioned between the outer bushing and inserts, and by seals positioned between the inserts and collars positioned around the axial ends of the pin.

The cartridge assembly disclosed in the '947 publication may provide certain benefits that are particularly important for some applications. However, it may have certain drawbacks. For example, providing both an inner bushing and an outer bushing may increase the complexity and cost of the assembly. The disclosed embodiments may help solve these problems.

### SUMMARY

One disclosed embodiment relates to a linkage pin joint assembly. The linkage pin joint assembly may include a portion of a first machine member having a first bore and a portion of a second machine member having a second bore. The linkage pin joint assembly may also include a linkage pin pivotally interconnecting at least the first and second machine members. The linkage pin may extend between the first and second machine members, and may be positioned at least partially within the first bore of the first machine member and the second bore of the second machine member. The linkage pin joint assembly may include the linkage pin extending at least partially through the first and second bores and pivotally supporting the first and second machine members relative to each other. The linkage pin may be coated with a diamond-like carbon (DLC) coating over at least a portion of an outer diameter surface of the linkage pin, the coating providing a contact layer between the outer diameter surface of the linkage pin and at least one of a mating inner diameter surface of a joint bushing positioned within one of the first and second bores through the first and second machine members and a mating inner diameter surface of one of the first and second bores.

Another disclosed embodiment relates to a linkage pin for use in a linkage pin joint assembly. The linkage pin may include an outer diameter surface prepared by a finishing operation that substantially removes surface asperities left by machining operations. The linkage pin may also include a coating applied over the outer diameter surface. The coating may include a sputtered underlayer, and an amorphous diamond-like carbon (a-DLC) outer layer.

A further disclosed embodiment relates to a method of manufacturing a linkage pin for use in a linkage pin joint assembly. The method may include finishing an outer diameter surface of the linkage pin using a finishing process that substantially removes surface asperities left by machining operations. The method may further include depositing an underlayer over the outer diameter surface of the linkage pin by sputtering with a transition metal carbide target, and applying an outer layer of diamond-like carbon (DLC) over the underlayer.

### BRIEF DESCRIPTION OF THE DRAWINGS

FIG. 1 is a perspective view of an exemplary machine including linkage pin joint assemblies according to the present disclosure;

FIG. 2 is a perspective view of another exemplary machine including linkage pin joint assemblies according to the present disclosure;

FIG. 2A is an enlarged cross section of the identified portion in the perspective view of FIG. 2, illustrating a cross-sectional view of a linkage pin in a linkage pin joint assembly;

FIG. 3 is a perspective view of a portion of an exemplary machine including multiple linkage pin joint assemblies according to the present disclosure; and

FIGS. 3A and 3B illustrate cross-sectional views of exemplary linkage pins of different lengths that may be used in linkage pin joint assemblies for pivotally interconnecting various members of the machine shown in FIG. 3.

### DETAILED DESCRIPTION

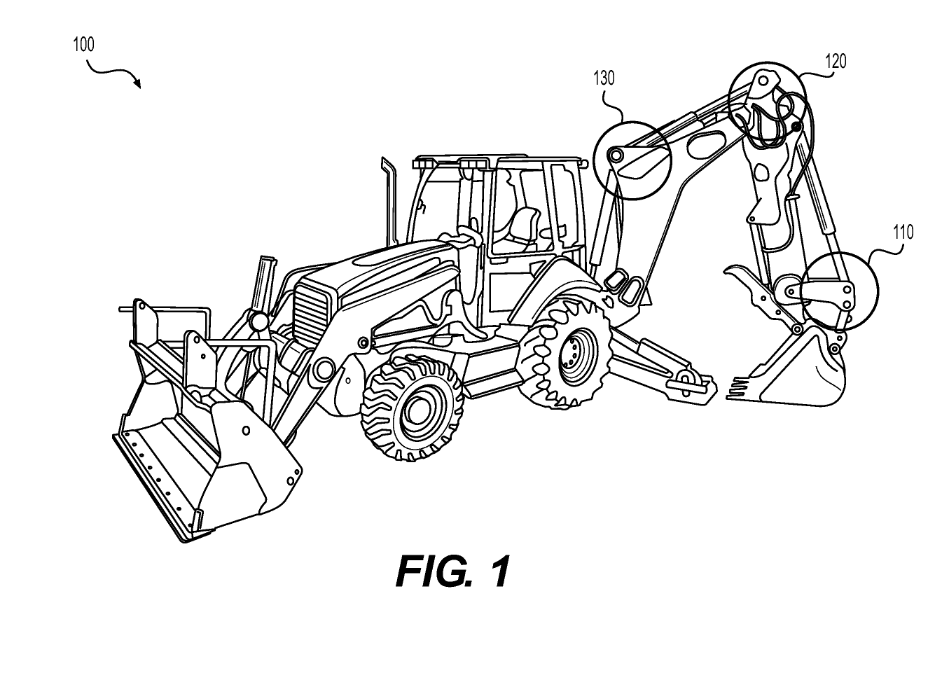

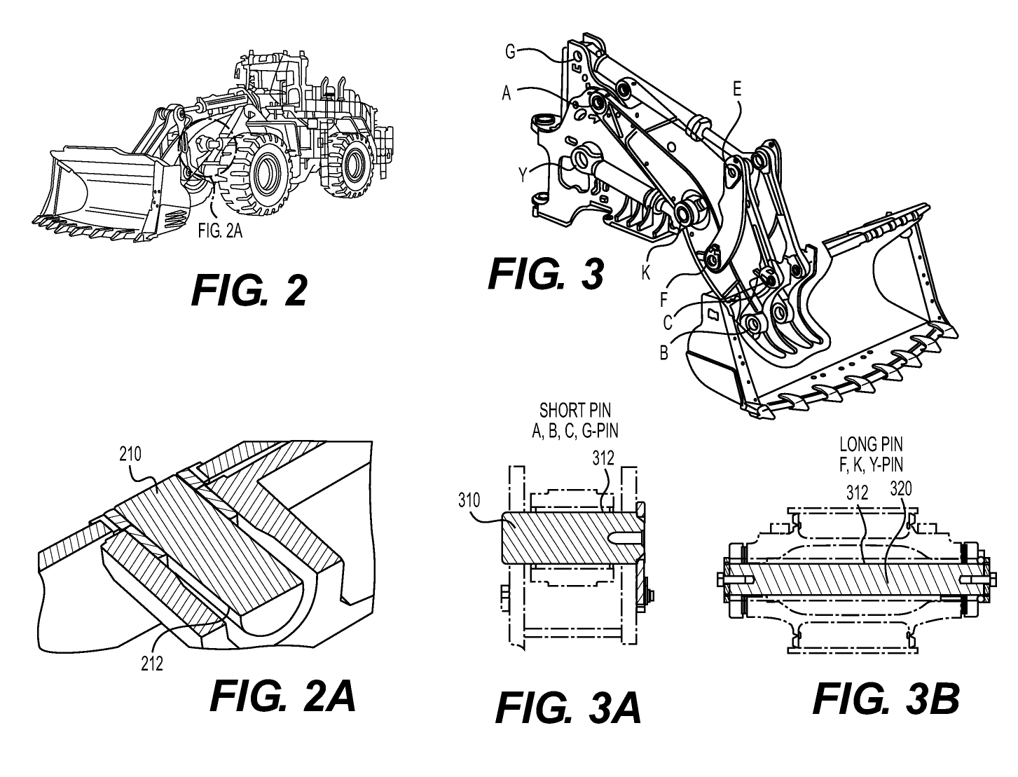

FIG. 1 illustrates an exemplary machine 100 including multiple linkage pin joint assemblies 110, 120, and 130. The exemplary machine 100 may include multiple systems and components that cooperate to excavate and load earthen material onto a nearby haul vehicle. The machine 100 illustrated in FIG. 1 is a backhoe loader. However, the machine 100 may embody any of a number of different types of machines such as a backhoe, a front shovel, a wheel loader (such as the machine illustrated in FIG. 2), a track-type tractor, an excavator, or another similar earthmoving, off-road, or on-road machine. The machine 100 may include, among other things, an implement system, a powertrain, and an operator station for manual control of the implement system and powertrain. The implement system may be driven by the powertrain to repetitively move a work tool between a dig location and a dump location, for example, over a haul vehicle during completion of a particular work cycle. The implement system may be configured to move the work tool in different manners during different work cycles, if desired.

As shown in FIG. 1, the disclosed implement system may include a linkage structure that cooperates with fluid actuators to move a work tool. Specifically, the implement system of machine 100 may include a boom that is pivotally connected to a frame of the machine 100 and vertically movable by a pair of hydraulic cylinders (only one shown in FIG. 1). The implement system may also include a stick or arm that is pivotally connected between the boom and a work tool, and movable by another hydraulic cylinder. The implement system may further include a single hydraulic cylinder operatively connected to vertically pivot the work tool relative to the stick. A greater or lesser number of fluid actuators may be included within the implement system and/or connected in a manner other than described above, if desired. Although the fluid actuators are shown in FIG. 1 for manipulating the implement system, it will be appreciated that the implement system may include other types of actuators known in the art, such as electric motors, for example. As shown in FIG. 1, linkage pin joint assemblies may be provided to pivotally interconnect various members of the machine 100. Linkage pin joint assembly 110, for example, may pivotally interconnect one end of a hydraulic cylinder and a hinge plate mounted at a distal end of the stick of the machine 100. The linkage pin joint assembly 110 may also include one or more linkage pins that pivotally interconnect the hinge plate, one or more links, and the work tool, such as the bucket shown in FIG. 1.

Referring to FIGS. 2 and 2A, each linkage pin joint assembly may include a linkage pin 210 that is supported within bores passing at least partially through two or more machine members that are pivotally interconnected. In the example shown in FIG. 2A, only one axial end of the linkage pin 210 is shown. The axial end of the linkage pin may be further supported within joint bushings that are fitted into the bores defined in the pivotally interconnected machine members. One of ordinary skill in the art will recognize that in some implementations the linkage pin may be press fit or otherwise joined to at least one of the pivotally interconnected machine members without the presence of a joint bushing or sleeve between the pin and the machine member.

In various exemplary implementations, the machine members may comprise one or more end or intermediate portions of a boom coupled to a frame of the machine, a stick coupled to the boom, and a work implement coupled to the stick. In addition or alternatively, a machine member may comprise one or more hinge plates or other protruding components or bosses coupled to or integral with one of the frame, the boom, the stick, or the work implement. A machine member may also comprise a fluid actuator having a first end pivotally coupled to one machine member and a second, opposite end pivotally coupled to a second machine member. A first machine member of two pivotally interconnected machine members may have a first bore extending at least part way through the first machine member. A second machine member of the two pivotally interconnected machine members may have a second bore through at least a portion of the second machine member. The first and second bores of the first and second machine members may be axially aligned, and a linkage pin may extend between the first and second machine members. The linkage pin may be positioned at least partially within each of the first and second bores in order to pivotally interconnect the first and second machine members. In some implementations a joint bushing may also be provided in one or more of the bores through the machine members, with a central axial bore being defined through the joint bushing. The joint bushing may or may not be press fit into one or more of the bores through the machine members. In some implementations the joint bushing may be free to rotate relative to the machine members. A linkage pin, such as linkage pin 210 of FIG. 2A, linkage pin 310 of FIG. 3A, or linkage pin 320 of FIG. 3B, may extend at least partially through the bores defined in the pivotally interconnected machine members, and may be secured in various ways. The linkage pin may rotate relative to the joint bushing, if one is provided, and relative to at least one of the pivotally interconnected machine members.

As shown in the cross-sectional views of the implementations of FIGS. 2A, 3A, and 3B, the linkage pin 210, 310, 320 may be positioned coaxially inside the bores defined in the pivotally interconnected machine members. As one of the machine members is moved relative to the other machine member through activation of a fluid actuator, electric motor, or other driving means coupled between the machine members, the linkage pin may rotate relative to at least one of the machine members. In order to facilitate such rotation, the outer diameter surface of the pin 210, 310, 320 may be coated with a diamond-like carbon (DLC) coating 212, 312 to reduce friction between the mating parts. The coating may provide a contact layer between the outer diameter surface of the linkage pin and at least one of a mating inner diameter surface of a joint bushing positioned within one of the first and second bores through the first and second machine members and a mating inner diameter surface of one of the first and second bores.

DLC as used herein refers to carbon based thin films, which may include amorphous diamond-like carbon (a-DLC), or ta-C for tetrahedral amorphous carbon. a-DLC may be further classified as amorphous carbon (a-C), or hydrogenated amorphous carbon (a-C:H). Alternative implementations may include coating an inner diameter surface of the central axial bore through the joint bushing or an inner diameter surface of a bore defined in one or more machine members, rather than or in addition to the outer diameter surface of the linkage pin. In a disclosed implementation, at least the outer diameter surface of the linkage pin may be provided with an isotropic surface finish and a hard thin film that includes the DLC coating over the isotropic surface finish.

Diamond-like carbon (DLC) thin films belong to a material family possessing low friction, high wear resistance, high scuffing resistance, and high galling resistance compared to steel. Galling failure is known to occur during the sliding contact between the linkage pins and joint bushings or between the linkage pins and machine members in linkage pin joint assemblies, particularly under high load applications. High load applications, such as incurred on larger, heavy-duty machinery, have typically mitigated the risk of galling through the use of sleeve bearings positioned around the outer diameter surface of the linkage pins between the pins and the joint bushings. The use of sleeve bearings adds additional cost and design complexity. The hard thin film coating including DLC applied over the outer diameter surface of the linkage pin may eliminate the need for a sleeve bearing between the pin and the joint bushing in high load applications, such as on large earth-moving tractors, excavators, and bulldozers. The hard thin film coating including DLC may also provide a desirable alternative to hard chromium plating, which has been used for some heavily loaded linkage pins used in heavy machinery applications. Some safety regulations, such as the Registration, Evaluation, Authorisation and Restriction of Chemicals (REACH) regulation of the European Union (EU), which came into effect in 2006, continue to be tightened, and may soon heavily restrict the use of hard chrome plating (HCP). The U.S. Occupational Safety and Health Administration (OSHA) may also soon pass legislation with restrictions on the use of HCP.

Linkage pins 210, 310, 320 of FIGS. 2A, 3A, 3B, respectively, may be initially prepared for coating by performing an isotropic finishing process or other finishing process to the outer diameter surface of the pin. The isotropic finishing substantially removes surface asperities while maintaining the integrity of the underlying material of the pin. Surface asperities are the peaks and valleys that cause unevenness or roughness of the surface as a result of machining operations. In an exemplary implementation, the isotropic finishing process may use oxalic acids or other chemicals to gently oxidize the outer diameter surface of the pin. This step helps to render any surface asperities left by earlier machining processes more susceptible to micro-honing. The micro-honing may be performed by tumbling the linkage pin in a chamber with non-abrasive finishing stones such as ceramic beads. The isotropic finishing process is a technique of final machining in a controlled and gentle manner that results in removal of most of the positive or peak surface areas left behind by other machining operations. One of ordinary skill in the art will recognize that other final surface preparation processes may be performed in order to substantially remove surface asperities. “Substantially remove surface asperities” as used throughout this application refers to removal of at least 70% of the peaks and valleys that cause unevenness or roughness of the surface as a result of machining operations.

According to various exemplary implementations, the outer diameter surface of the pin may have an arithmetic average surface roughness Ra (hereinafter Ra) of less than about 0.1 μm. The outer diameter surface of the pin may be finished to the desired Ra using any of a number of known machining, or surface finishing, processes. The outer diameter surface may also be subjected to the isotropic surface finishing processes discussed above such that at least 70% of the peaks occurring as a result of the machining or finishing processes used to achieve the desired Ra are removed. An isotropic surface finish, as described herein, refers to a particular surface finish in which peaks of the surface asperities have been substantially removed, and does not insinuate a specific process for providing the isotropic surface finish. Such processes may include any known chemical and/or mechanical processes, including vibratory finishing processes, to achieve the desired isotropic surface finish.

The coating 212, 312 shown in FIGS. 2A, 3A, and 3B, preferably has a nano-hardness of at least about 10 gigapascals (GPa), and even more preferably, at least about 20 GPa. As discussed above, the coating may include an amorphous diamond-like carbon layer (a-DLC), which provides low friction and high wear resistance. The outer diameter surface of the linkage pin may be first provided with an isotropic finish, and then sputtered with an underlayer of a first radial thickness that may include carbon doped with one or more transition metals. The sputtering of an underlayer may assist in the adhesion of an outer layer of a-DLC, as well as providing additional support for the outer layer. The sputtering process may form the underlayer by sputtering with a transition metal carbide target. The transition metal carbide target may include one or more elements from the chromium group (also known as group VIB) on the periodic table, including Chromium (Cr) and Tungsten (W). Even more preferably, the sputtering process may form the underlayer by sequentially sputtering transition metal targets with an inert gas, and sputtering transition metal and transition metal carbide targets with a reactive gas. The sputtering process is a physical vapor deposition process that involves ejecting material from a target that is a source of the desired elements to the receiving surface, which is the outer diameter surface of the linkage pin. After the sputtering process has formed the underlayer, a plasma assisted chemical vapor deposition (PACVD) process may be performed in a vacuum chamber to deposit amorphous hydrogenated carbon (a-C:H) from a gas phase over the underlayer. The deposition of the hydrogenated carbon from a gas phase results in an outer layer of a-DLC. In various implementations, tetrahedral amorphous carbon (ta-C) may be used to achieve an even harder coating with a hardness in a range from approximately 40-80 GPa. The ta-C outer layer may be applied in certain applications without first sputtering an underlayer. The a-DLC outer layer of the coating may also be doped with transition metal carbides or other elements, such as silicon. The carbon content of the a-DLC outer layer is also preferably within a range from approximately 60-80 atomic percent. Preferably, the coating has an elasticity sufficient to withstand a load range of applications experiencing contact pressure of up to 2 GPa.

The outer layer of a-DLC in coating 212, 312 may be deposited to a second radial thickness that is approximately twice the first radial thickness of the sputtered underlayer. The total thickness of the underlayer and the a-DLC outer layer is preferably within a range from approximately 2.0-20 μm. Since the thickness of this coating is negligible, there is no need to change existing clearance designs for the linkage pin and joint bushing, or for the bores defined in other machine members. As a result, existing linkage pin assemblies may be retrofitted to include linkage pins comprising the above-disclosed features.

The isotropic surface finish provided to the outer diameter surface of the linkage pin, as discussed above, may provide better support for the coating than a surface not having an isotropic surface finish. For example, if the hard DLC coating is deposited on a surface having sharp peaks left by machining processes, such as grinding, the stress on the peaks may be high and may induce cracking of the coating. Ultimately, cracking of the coating may lead to the separation and/or breaking off of portions of the coating relative to the outer diameter surface of the pin. Since the isotropic surface finish has the sharp peaks removed, a better support base for the coating may be provided.

In addition, the isotropic surface finish in combination with the hard thin film coating 212, 312 may help to break in the inner diameter surface of the central axial bore through a joint bushing, or the inner diameter surface of a bore defined in another machine member. In particular, since the hard thin film coating 212, 312 on the outer diameter surface of the linkage pin 210, 310, 320 is much harder than the inner diameter surface of the bore, the hard thin film coating 212, 312 may function to break in the inner diameter surface of the bore. If the isotropic surface finish were not provided on the outer diameter surface of the linkage pin, the hard thin film coating could include sharp surface peaks and may grind and wear the inner diameter surface of the bore. However, since the outer diameter surface of the linkage pin includes the isotropic surface finish, the hard thin film coating is less abrasive than if the outer diameter surface of the pin did not include the isotropic surface finish. As a result, an efficient and effective reduction of the Ra of the inner diameter surface of the joint bushing and/or bore defined in another machine member may be achieved as well. As an additional enhancement to the process of breaking in the inner diameter surface of the central axial bore, lubricating fluid may be added through lubrication channels (not shown) extending into the linkage pin 210, 310, 320.

### INDUSTRIAL APPLICABILITY

The disclosed linkage pin joint assemblies may be applicable to all types of heavy machinery, such as, for example, a backhoe loader, a front shovel, a wheel loader (such as the machine illustrated in FIG. 2), a track-type tractor, an excavator, or another similar earthmoving, off-road, or on-road machine, and may facilitate movement of the machines. The disclosed linkage pin joint assemblies may have various advantages over prior art linkage pin joint assemblies. For example, the disclosed linkage pin joint assemblies may be stronger and more durable than prior art linkage pin joint assemblies. In addition, manufacturing the disclosed linkage pin joint assemblies may cost less than manufacturing prior art linkage pin joint assemblies, may require less material than manufacturing prior art linkage pin joint assemblies, and may enable easier compliance with emerging safety and health regulations.

Linkage pin joint assemblies utilizing linkage pins comprising the hard thin film coatings in accordance with various implementations of this disclosure may include direct connections between the machine members, joint bushings, and the linkage pins that strengthen and improve the durability of the linkage pin joint assemblies. Specifically, the hard DLC coating may strengthen and improve the durability of the linkage pin joint assemblies by reducing susceptibility to vibrations, impacts, and wear.

The linkage pin joint assemblies may be configured to facilitate rotation of the joint bushings and/or other machine members relative to the linkage pins even when the linkage pins are solid (and thus capable of being manufactured without using costly machining, drilling, or casting processes). In particular, the relative rotation between the linkage pins, joint bushings, and/or other machine members may be facilitated by coating one or both of each linkage pin and joint bushing with a hard thin film coating including DLC to reduce friction and potential galling between the parts.

The linkage pin joint assemblies in accordance with various implementations of this disclosure may be configured to minimize the total amount of material required to manufacture the joint assemblies. Such minimization may be achieved by providing a hard thin film coating including DLC over the outer diameter surface of the linkage pins, which may eliminate the need for sleeve bearings or additional bushings, even under high load applications. The additional manufacturing step of first providing an isotropic finished outer diameter surface on the linkage pin before applying the hard thin film coating further enhances the ability of the joint assembly to withstand high loads. Elimination of intermediate sleeve bearings between the linkage pins and joint bushings also enhances the direct connections between the pivotally interconnected components as discussed above, and may strengthen and improve the durability of the linkage pin joint assemblies.

It will be apparent to those skilled in the art that various modifications and variations can be made to the disclosed linkage pin joint assemblies. Other embodiments will be apparent to those skilled in the art from consideration of the specification and practice of the disclosed processes and assemblies. It is intended that the specification and examples be considered as exemplary only, with a true scope being indicated by the following claims and their equivalents.

What is claimed is:

1. A linkage pin joint assembly, comprising:
a portion of a first machine member having a first bore;
a portion of a second machine member having a second bore; and
a linkage pin pivotally interconnecting at least the first and second machine members,
the linkage pin extending between the first and second machine members, and being positioned at least partially within the first bore of the first machine member and the second bore of the second machine member,
the linkage pin extending at least partially through the first and second bores and pivotally supporting the first and second machine members relative to each other, and
the linkage pin being coated with a diamond-like carbon (DLC) coating over at least a portion of an outer diameter surface of the linkage pin, the coating providing a contact layer between the outer diameter surface of the linkage pin and at least one of a mating inner diameter surface of a joint bushing positioned within one of the first and second bores through the first and second machine members and a mating inner diameter surface of one of the first and second bores.

2. The linkage pin joint assembly of claim 1, wherein the linkage pin comprises the outer diameter surface finished by an isotropic finishing process before application of the coating.

3. The linkage pin joint assembly of claim 1, wherein the linkage pin comprises the DLC coating being at least one of an amorphous diamond-like carbon (a-DLC) coating and a tetrahedral amorphous carbon (ta-C) coating applied over an underlayer comprising at least one element from the chromium group (group VIB).

4. The linkage pin joint assembly of claim 3, wherein the DLC coating is approximately twice the thickness of the underlayer.

5. The linkage pin joint assembly of claim 3, wherein a total thickness of the underlayer and the DLC coating on the outer diameter surface of the linkage pin falls within the range from approximately 2-20 μm.

6. The linkage pin joint assembly of claim 1, wherein the DLC coating comprises a carbon content within the range from approximately 60-80 atomic percent.

7. The linkage pin joint assembly of claim 1, wherein the DLC coating is applied using a plasma assisted chemical vapor deposition (PACVD) process.

8. The linkage pin joint assembly of claim 2, wherein an underlayer comprising at least one element from the chromium group (group VIB) is applied over the isotropic finished outer diameter surface of the pin, and the DLC coating is applied over the underlayer.

9. A linkage pin for use in a linkage pin joint assembly, the linkage pin comprising:
an outer diameter surface prepared by a finishing operation that substantially removes surface asperities left by machining operations; and
a coating applied over the outer diameter surface, the coating comprising:
a sputtered underlayer; and
an amorphous diamond-like carbon (a-DLC) outer layer.

10. The linkage pin of claim 9, wherein the linkage pin comprises the a-DLC outer layer applied over the underlayer, with the outer layer having a radial thickness that is approximately twice a radial thickness of the underlayer, and the underlayer comprises at least one transition metal.

11. The linkage pin of claim 9, wherein the a-DLC outer layer comprises a carbon content that falls within a range from approximately 60-80 atomic percent.

12. The linkage pin of claim 9, wherein a total thickness of the underlayer and the a-DLC outer layer falls within a range from approximately 2-20 μm.

13. The linkage pin of claim 9, wherein the a-DLC outer layer has a hardness that is greater than approximately 10 gigapascals (GPa).

14. The linkage pin of claim 9, wherein the a-DLC outer layer is applied using a plasma assisted chemical vapor deposition (PACVD) process.

15. The linkage pin of claim 9, wherein the underlayer is applied over an isotropic finished outer diameter surface of the linkage pin using a sputtering process, and the a-DLC outer layer is an amorphous hydrogenated carbon (a-C:H) layer applied from a gas phase over the underlayer.

16. A method of manufacturing a linkage pin for use in a linkage pin joint assembly, the method comprising:
finishing an outer diameter surface of the linkage pin using a finishing process that substantially removes surface asperities left by machining operations;
depositing an underlayer over the outer diameter surface of the linkage pin by sputtering with a transition metal carbide target; and
applying an outer layer of diamond-like carbon (DLC) over the underlayer.

17. The method of claim 16, wherein the underlayer is deposited to a first thickness, and the outer layer of DLC is deposited to a second thickness that is approximately two times the first thickness.

18. The method of claim 16, wherein the outer layer of DLC is deposited from a gas phase using a plasma assisted chemical vapor deposition (PACVD) process.

19. The method of claim 16, wherein the underlayer is deposited by sputtering with a transition metal carbide target including one or more elements from the chromium group (group VIB).

20. The method of claim 16, wherein the outer layer comprises a tetrahedral amorphous carbon (ta-C) layer having a hardness falling within a range from approximately 40-80 gigapascals (GPa).
